(19) United States
(12) Patent Application Publication
(10) Pub. No.: US 2025/0374492 A1
(43) Pub. Date: Dec. 4, 2025

(54) DISPLAY APPARATUS, HEAT TRANSFER CONTROL METHOD, AND ELECTRONIC DEVICE

(71) Applicant: Lenovo (Beijing) Limited, Beijing (CN)

(72) Inventors: Guowen ZHANG, Beijing (CN); Zhiqiang Zhou, Beijing (CN)

(21) Appl. No.: 19/216,698

(22) Filed: May 22, 2025

(30) Foreign Application Priority Data
May 31, 2024 (CN) 202410696300.1

(51) Int. Cl. H05K 7/20

(52) U.S. Cl. CPC H05K 7/20963; H05K 7/20981

(57) ABSTRACT

A display apparatus includes a display screen and a temperature adjustment apparatus. The display screen includes a display surface and a non-display surface facing away from the display surface. The temperature adjustment apparatus is arranged on a side of the non-display surface of the display screen and configured to adjust a temperature difference among different areas of the display screen.

### CROSS-REFERENCE TO RELATED APPLICATION

The present disclosure claims priority to Chinese Patent Application No. 202410696300.1, filed on May 31, 2024, the entire content of which is incorporated herein by reference.

### TECHNICAL FIELD

The present disclosure relates to the screen heat transfer technology field and, more particularly, to a display apparatus, a heat transfer control method, and an electronic device.

### BACKGROUND

Wireless heat dissipation devices are necessary components in electronic devices. However, existing heat dissipation devices are mainly used to dissipate heat for components that generate significant amount of heat, such as central processing units and image processors. For some specific forms of electronic devices, existing heat dissipation devices cannot meet the needs.

### SUMMARY

An aspect of the present disclosure provides a display apparatus, including a display screen and a temperature adjustment apparatus. The display screen includes a display surface and a non-display surface facing away from the display surface. The temperature adjustment apparatus is arranged on a side of the non-display surface of the display screen and configured to adjust a temperature difference among different areas of the display screen.

An aspect of the present disclosure provides a heat transfer control method, applied to a display apparatus. The method includes, in response to a temperature difference among different areas of a display screen, controlling a temperature adjustment apparatus to adjust the temperature difference of different areas of the display screen.

An aspect of the present disclosure provides an electronic device, including a display apparatus and a first space. The display apparatus includes a display screen and a temperature adjustment apparatus. The display screen includes a display surface and a non-display surface facing away from the display surface. The temperature adjustment apparatus is arranged on a side of the non-display surface of the display screen and configured to adjust a temperature difference among different areas of the display screen. The first space is neighboring to a heat generation element of the electronic device. The display apparatus is able to switch between a first status and a second status. In the first status, the display apparatus is at least partially accommodated in the first space. In the second status, the display apparatus extends out of the first space.

### BRIEF DESCRIPTION OF THE DRAWINGS

FIG. 1 illustrates a schematic structural diagram of a display apparatus according to some embodiments of the present disclosure.

FIG. 2 illustrates a schematic structural diagram of another display apparatus according to some embodiments of the present disclosure.

FIG. 3 illustrates a schematic structural diagram of another display apparatus according to some embodiments of the present disclosure.

FIG. 4 illustrates a schematic flowchart of a heat transfer control method according to some embodiments of the present disclosure.

FIG. 5 illustrates a schematic flowchart of another heat transfer control method according to some embodiments of the present disclosure.

FIG. 6 illustrates a schematic diagram showing an application scene of a display apparatus according to some embodiments of the present disclosure.

FIG. 7 illustrates a schematic structural diagram of an electronic device according to some embodiments of the present disclosure.

### REFERENCE NUMERALS

| | | |
|---|---|---|
| 1 Display screen | 2 Temperature adjustment apparatus | 3 Temperature monitor |
| 11 Display surface | 12 Non-display surface | 21 Heat transfer layer |
| 211 Liquid channel | 2111 Curved channel segment | 2112 Straight channel segment |

### DETAILED DESCRIPTION OF THE EMBODIMENTS

To make the purpose, features, and advantages of the present disclosure more apparent and easier to understand, the technical solutions of embodiments of the present disclosure are described in detail below in conjunction with the accompanying drawings of embodiments of the present disclosure. Apparently, the described embodiments are only some embodiments of the present disclosure, and not all embodiments. Based on embodiments of the present disclosure, all other embodiments obtained by those skilled in the art without creative effort shall fall within the scope of the present disclosure.

In the following description, “some embodiments” describe a subset of all possible embodiments. However, “some embodiments” may be the same or different subsets of all possible embodiments and can be combined with each other when there is no conflict.

In the following description, the terms “first/second” are merely used to distinguish similar objects and do not imply a specific order of the objects. “first/second” may, where permissible, be interchanged in specific sequences or orders to enable embodiments of the present disclosure described here to be implemented in sequences other than those illustrated or described.

Unless otherwise defined, all technical and scientific terms used in the present specification can have the same meanings as commonly understood by those skilled in the art. The terms used herein are solely for the purpose of describing embodiments of the present disclosure and are not intended to limit the present disclosure.

The technical solutions of the present disclosure are further described in detail below with reference to the accompanying drawings and specific embodiments.

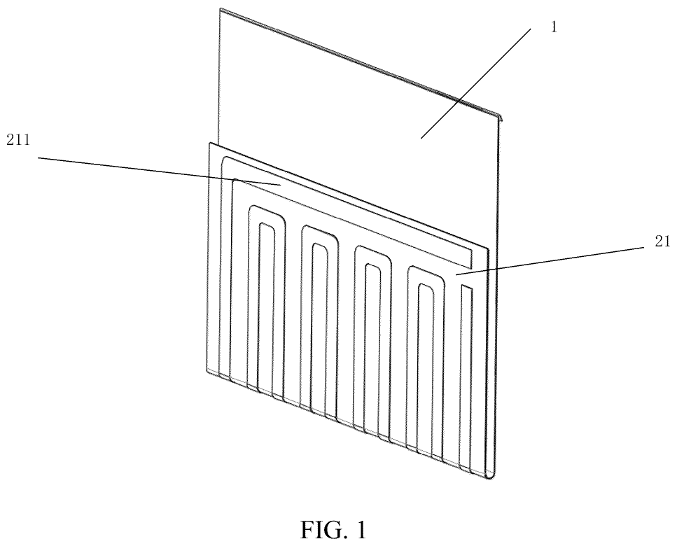

FIG. 1 illustrates a schematic structural diagram of a display apparatus according to some embodiments of the present disclosure.

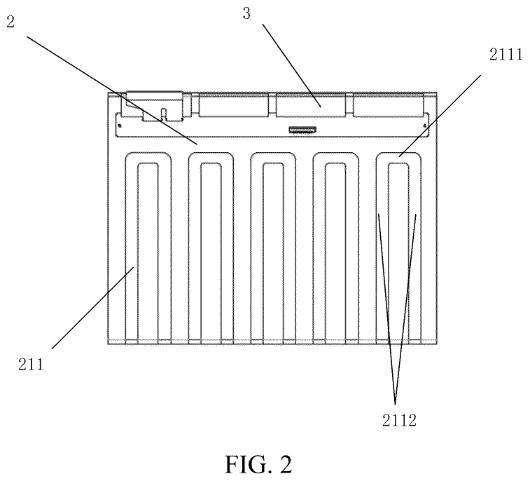

FIG. 2 illustrates a schematic structural diagram of another display apparatus according to some embodiments of the present disclosure.

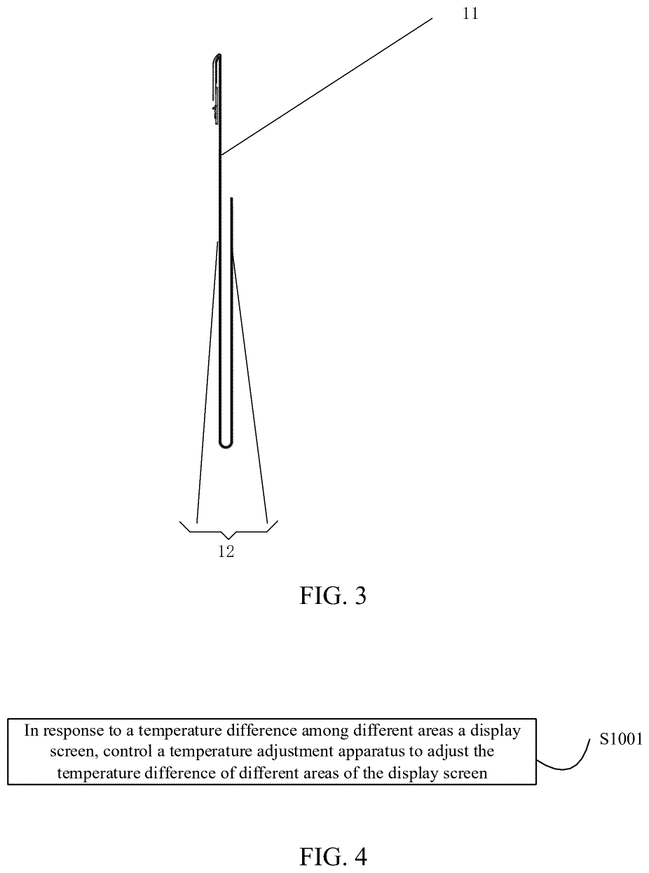

FIG. 3 illustrates a schematic structural diagram of another display apparatus according to some embodiments of the present disclosure.

Referring to FIGS. 1, 2, and 3, the display apparatus of embodiments of the present disclosure includes a display screen 1 and a temperature adjustment apparatus 2. The display screen 1 includes a display surface 11 and a non-display surface 12 facing away from the display surface 11. The temperature adjustment apparatus 2 is arranged on a side of the display screen 1 for the non-display surface 12 and is configured to adjust temperature differences at different areas of the display screen 1. The display surface 11 can be configured to display an image, video, or other visual information. The non-display surface 12 is arranged on the opposite surface of the display surface 11. The non-display surface 12 can be connected to an electronic assembly, a connection port, the temperature adjustment apparatus 2, etc., and can be configured to support other functions of the display screen 1. During operation, the display screen 1 can have temperature differences between different areas of the display screen 1 due to different heat generation from the assemblies in different areas. The temperature adjustment apparatus 2 can be configured to reduce the temperature differences among different areas of the display screen 1.

In the display apparatus of embodiments of the present disclosure, the temperature detection of the display apparatus can be realized in a thin space on the side of the non-display surface 12 of the display screen 1. The temperature differences among different areas of the display screen 1 can be adjusted to prevent abnormal color display issues on the display screen 1. To adjust the temperature differences among different areas of the display screen 1, a specific area, e.g., a hot area, can be dissipated to cause the temperature of the specific area to reduce to reduce the temperature difference between the specific area and other areas of the display screen 1. In some other embodiments, a heat transfer structure can be configured to cause the different areas of the display screen 1 to perform heat transfer to balance the temperature to reduce the temperature difference.

In some embodiments, the temperature adjustment apparatus 2 includes a heat transfer layer 21. The heat transfer layer 21 is attached to the non-display surface 12 of the display screen 1. The heat transfer layer 21 can include one or more of a solid heat transfer structure and a liquid heat transfer structure. The heat transfer layer 21 can be made of a material with good thermal conductivity. The heat transfer layer 21 can be attached to the non-display surface 12 through physical adhesion, bonding, or other fixed connections. The heat transfer layer 21 can be configured to conduct and dissipate the heat generated during the operation of the display screen 1. The heat transfer layer 21 can include a solid heat transfer structure, such as a flexible graphite sheet and a thermally conductive silicone pad. Alternatively, the heat transfer layer 21 can include a liquid heat transfer structure, such as a liquid channel 211, for liquid cooling. For example, the heat transfer layer 21 can include a liquid channel 211 storing coolant. The coolant can circulate within the heat transfer layer 21. The heat transfer layer 21 may also integrate heat flow in the heat transfer layer 21. The heat transfer layer 21 can further include an integrated heat dissipation structure, including the flexible graphite sheet and the liquid channel 211 for liquid cooling. The heat of the display screen 1 can first be conducted by the flexible graphite sheet and then further by the liquid channel 211 for liquid cooling.

In the display apparatus of embodiments of the present disclosure, the temperature detection of the display apparatus can be realized in the thin space on the side of the non-display surface 12 of the display screen 1. The heat transfer layer 21 can adjust the temperature difference among different areas of the display apparatus 1 through the solid heat transfer structure and/or the liquid heat transfer structure to prevent the abnormal color display issues on the display screen 1.

In some embodiments, the temperature adjustment apparatus 2 can include an air guide structure. The air guide structure can be configured to guide a heat dissipation air flow to the display screen 1. The air guide structure can be formed by one or more fans and air channels. The air channels can be formed on the non-display surface 12 of the display screen 1. The fans can blow the heat dissipation air flow to the display screen 1. The fans can be configured with different sizes and rotation speeds to adapt to different heat dissipation needs.

In the display apparatus of embodiments of the present disclosure, the temperature detection of the display apparatus can be realized in the thin space on the side of the non-display surface 12 of the display screen 1. The temperature adjustment apparatus 2 can adjust the temperature difference among different areas of the display screen 1 through the air cooling heat transfer structure to prevent the abnormal color display issues on the display screen 1.

In some embodiments, the display screen 1 can bend and deform after the external force applied to the display screen 1 reaches the preset external force threshold. The heat transfer layer 21 can bend and deform with the display screen 1. The display screen 1 can be a flexible screen. The flexible screen can be rolled or folded. In the rolled or folded status, the display screen 1 can maintain the display performance. The preset external force threshold can include the threshold of the maximum force that the display screen 1 can withstand without being damaged. The heat transfer layer 21 can be made of a flexible material. The flexible material can maintain the performance when the display screen 1 bends.

In the display apparatus of embodiments of the present disclosure, the temperature detection of the display apparatus can be realized in the thin space on the side of the non-display surface 12 of the display screen 1. The heat transfer layer 21 can bend and deform with the display screen 1 and adjust the temperature difference among different areas of the display screen 1 to prevent the abnormal color display issues on the display screen 1.

In some embodiments, the liquid heat transfer structure included in the temperature adjustment apparatus 2 includes a liquid channel 211 formed inside the liquid heat transfer structure. The liquid channel 211 includes curved channel segments 2111 and a plurality of parallel straight channel segments 2112. A curved channel segment 2111 is arranged on one side of two neighboring straight channel segments 2112 and is configured to connect the two neighboring straight channel segments 2112. The liquid in the liquid channel 211 can transfer the heat of the display screen 1. The liquid channel 211 can be embedded in a flexible and bendable polymer material, which is arranged on the side of the non-display surface 12. The liquid in the liquid channel 211 can include a non-electrical-conductive fluid, such as a fluorinated liquid. The flexible and bendable polymer material can include polyimide (PI) or high-elasticity rubber. A thickness of the polymer material can be less than 0.15 mm. The curved channel segments 2111 and the plurality of parallel straight channel segments 2112 can be configured to increase the heat transfer area of the temperature adjustment apparatus 2.

In the display apparatus of embodiments of the present disclosure, the temperature detection of the display apparatus can be realized in the thin space on the side of the non-display surface 12 of the display screen 1. According to the detected temperature difference among the different areas of the display screen 1, the liquid in the liquid channel 211 can be driven to circulate to transfer the heat of the display screen 1 to prevent the abnormal color display issues on the display screen 1.

In some embodiments, the display apparatus can further include a fluid driver configured to be connected to the liquid channel 211 of the temperature adjustment apparatus 2 to form a circulating heat transfer loop. The display apparatus can also include a temperature monitor 3 configured to measure the temperature of the display apparatus. The temperature monitor 3 can be connected to the liquid driver and can respond to the temperature difference among the areas of the display screen 1 being greater than the temperature threshold to control the liquid driver to drive the liquid in the circulating heat transfer loop to flow to adjust the temperature difference of different areas of the display screen 1. The liquid driver can include a vibration membrane and a chamber body. The vibration membrane can include a micro-piezoelectric vibration membrane. The vibration membrane can vibrate in the chamber body at different vibration frequencies to drive the liquid to circulate in the liquid channel 211. The temperature monitor 3 can monitor the temperatures of different areas of the display screen 1 to monitor the temperature of the liquid in the liquid channel 211 in real-time. The temperature threshold can include the preset threshold temperature of the display screen 1. When the temperature difference among the areas of the display screen 1 is greater than the threshold temperature, the temperature monitor 3 can control the fluid driver to drive the liquid in the circulating heat transfer loop to flow.

In the display apparatus of embodiments of the present disclosure, the temperature detection of the display apparatus can be realized in the thin space on the side of the non-display surface 12 of the display screen 1. In response to the temperature difference among the areas of the display screen 1 being greater than the temperature threshold, the fluid driver can be controlled to drive the liquid in the circulating heat transfer loop to flow to drive the fluid in the liquid channel 211 to circulate to transfer the heat of the display screen 1 and adjust the temperature difference of different areas of the display screen 1 to prevent the abnormal color display issues on the display screen 1.

In some embodiments, the fluid driver can control the vibration membrane in the fluid driver to vibrate at different vibration frequencies according to different temperature differences among the areas of the display screen 1 to adjust the flow speed of the liquid in the liquid channel 211. The temperature monitor 3 can be connected to the fluid driver. If the temperature difference among the areas of the display screen 1 is detected to be greater than the preset temperature threshold, the temperature monitor 3 can transmit the temperature difference data to the liquid driver. The liquid driver can adjust the vibration frequency for the vibration membrane according to the data. The vibration frequency can be changed to affect the flow speed of the liquid in the liquid channel 211. By increasing the vibration frequency of the vibration membrane, the flow speed of the liquid in the liquid channel 211 can increase, while by decreasing the vibration frequency of the vibration membrane, the flow speed of the liquid in the liquid channel 211 can decrease.

In the display apparatus of embodiments of the present disclosure, the temperature detection of the display apparatus can be realized in the thin space on the side of the non-display surface 12 of the display screen 1. According to the detected temperature difference of different areas of the display screen 1, the vibration frequency of the vibration membrane of the liquid driver can be adjusted to control the vibration membrane of the liquid driver to vibrate at different vibration frequencies to drive the liquid in the liquid channel 211 to circulate at differ flow speeds to transfer the heat of the display screen 1 and adjust the temperature difference of different areas of the display screen 1 to prevent the abnormal color display issues on the display screen 1.

The processing process of the heat transfer control method of the present disclosure is further described.

FIG. 4 illustrates a schematic flowchart of a heat transfer control method according to some embodiments of the present disclosure. The method includes the following steps.

At S1001, in response to the temperature difference among different areas of the display screen, the temperature adjustment apparatus is controlled to adjust the temperature difference of different areas of the display screen.

In some embodiments, the heat transfer control method can be applied to the display apparatus. The display apparatus can include the display screen 1, including the display surface 11 and the non-display surface 12 facing away from the display surface 11, and the temperature adjustment apparatus 2. The temperature adjustment apparatus 2 can be arranged on the side of the non-display surface 12 of the display screen 1 and configured to adjust the temperature difference of different areas of the display screen 1.

For example, the different areas of the display screen 1 can include a top member of the display screen 1 and a bottom member of the display screen 1. In response to the temperature difference between the top member of the display screen 1 and the bottom member of the display screen 1, the temperature adjustment apparatus 2 can be controlled to adjust the top member of the display screen 1 and the bottom member of the display screen 1 to cause the temperature difference between the top member of the display screen 1 and the bottom member of the display screen 1 to maintain within a determined temperature range.

In the heat transfer control method of embodiments of the present disclosure, the temperature can be detected for the display screen 1. In response to the temperature difference among different areas of the display screen, the temperature adjustment apparatus can be controlled to adjust the temperature difference of different areas of the display screen to prevent the abnormal color display issues on the display screen 1. The temperature difference of different areas of the display screen 1 can be adjusted by dissipating heat of a certain area, e.g., a hot area, to cause the temperature of the certain area to decrease to decrease the temperature difference between the certain area and other areas of the display screen 1, or by transferring the heat between different areas of the display screen 1 through the heat transfer structure to balance the temperature to decrease the temperature difference.

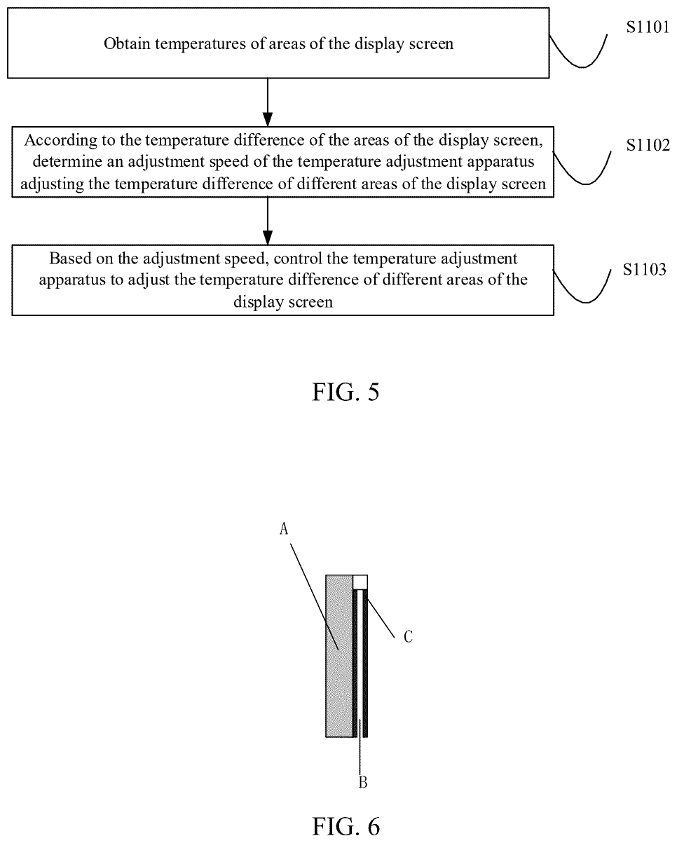

FIG. 5 illustrates a schematic flowchart of another heat transfer control method according to some embodiments of the present disclosure. As shown in FIG. 5, in step S1001, controlling the temperature adjustment apparatus to adjust the temperature difference of different areas of the display screen includes the following steps.

At S1101, temperatures of areas of the display screen are obtained.

At S1102, according to the temperature difference of the areas of the display screen, an adjustment speed of the temperature adjustment apparatus adjusting the temperature difference of different areas of the display screen is determined.

At S1103, based on the adjustment speed, the temperature adjustment apparatus is controlled to adjust the temperature difference of different areas of the display screen.

In some embodiments, the temperature monitor 3 can obtain and measure the temperatures of the areas of the display screen 1. When the temperature difference between the areas of the display screen 1 is greater than the threshold temperature, the temperature monitor 3 can send the temperature difference of the areas of the display screen 1 to the fluid driver. The fluid driver can then determine the vibration frequency of the vibration membrane inside the fluid driver according to the temperature difference of the areas of the display screen 1 to control the vibration membrane inside the fluid driver to vibrate at different vibration frequencies to drive the liquid in the circulating heat transfer loop to flow to adjust the temperature difference of different areas of the display screen 1.

In the heat transfer control method of embodiments of the present disclosure, the temperature detection of the display apparatus can be realized. According to the detected temperature difference of different areas of the display screen 1, the adjustment speed of the temperature adjustment apparatus adjusting the temperature difference of different areas of the display screen 1 can be determined. According to the determined adjustment speed, the temperature adjustment apparatus can be controlled to adjust the temperature difference of different areas of the display screen to prevent the abnormal color display issues on the display screen 1.

FIG. 6 illustrates a schematic diagram showing an application scene of a display apparatus according to some embodiments of the present disclosure.

As shown in FIG. 6, the application scene can be applied to an electronic device including a flexible screen. The electronic device can include a laptop computer. The electronic device can include a first space. The first space can be neighboring to a heat generation element of the electronic device. The display apparatus can switch between the first status and the second status. In the first status, the display apparatus can be at least partially accommodated in the first space. In the second status, the display apparatus can extend out from the first space. FIG. 6 is a side view of the display apparatus of embodiments of the present disclosure. The display apparatus includes a flexible screen A, a liquid micro-channel B, and a rubber film layer C. The flexible screen A can bend and deform when an external force, applied to the flexible screen A, reaches the preset external force threshold. The liquid micro-channel B and the rubber film layer C can bend and deform with the flexible screen A. The liquid micro-channel B and the rubber film layer C can be arranged on the side of the non-display surface of the flexible screen A. The liquid in the liquid micro-channel B can transfer the heat of the flexible screen A to adjust the temperature difference of different areas of the flexible screen A.

The application scene of the display apparatus of FIG. 6 is merely an exemplary implementation of embodiments of the present disclosure. The application scene of the display apparatus of the present disclosure can include but is not limited to the application scene of the display apparatus shown in FIG. 6.

Embodiments of the present disclosure further provide an electronic device and a non-transitory computer-readable storage medium.

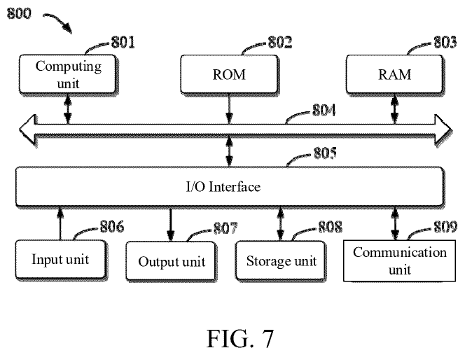

FIG. 7 illustrates a schematic structural diagram of an electronic device 800 according to some embodiments of the present disclosure. The electronic device can include various types of digital computers, e.g., laptops, desktops, workstations, personal digital assistants, servers, blade servers, mainframes, and other suitable computers. The electronic device can also include various types of mobile apparatuses, such as personal digital assistants, cellular phones, smartphones, wearable devices, and other similar computing apparatuses. The members, connection relationships of the members, and functions of the members of the present disclosure are merely examples and are not intended to limit the implementation described in the specification and/or claimed in the present disclosure.

As shown in FIG. 7, the electronic device 800 includes a computing unit 801. The computing unit 801 can be configured to perform various suitable actions and processes according to the computer program stored in read-only memory (ROM) 802 or loaded from a storage unit 808 into random-access memory (RAM) 803. The RAM 803 can also store various programs and data required by the operation of the electronic device 800. The computing unit 801, the ROM 802, and the RAM 803 are connected to each other via a bus 804. An input/output (I/O) interface 805 is also connected to the bus 804.

The plurality of members of the electronic device 800 can be connected to the I/O interface 805, which include an input unit 806, e.g., a keyboard and a mouse, an output unit 807, e.g., various types of displays and speakers, a storage unit 808, e.g., magnetic discs and optical discs, and a communication unit 809, e.g., a network card, a modem, or a wireless communication transceiver. The communication unit 809 can allow the electronic device to exchange information/data with other devices through computer networks such as Internet and/or various telecommunication networks.

The computing unit 801 can be any general-purpose or special-purpose processing assembly having processing and computation capabilities. For example, the computing unit 801 can include but is not limited to a central processing unit (CPU), a graphics processing unit (GPU), a specialized AI computing chip, a computing unit running machine learning algorithms, a digital signal processor (DSP), and any suitable processors, controllers, or microcontrollers. The computing unit 801 can be configured to perform the methods and processes described above, such as the device connection method. For example, in some embodiments, the device connection method can be implemented as a computer software program, which is tangibly stored in a machine-readable medium, e.g., storage unit 808. In some embodiments, a part or all of the computer program can be loaded or installed onto the electronic device 800 via the ROM 802 and/or the communication unit 809. When the program is loaded into the RAM 803 and executed by the computing unit 801, one or more steps of the device connection method described above can be performed. In other embodiments, the computing unit 801 can be configured to execute the device connection method in any other suitable manner (e.g., via firmware).

Various implementations of the systems and technologies described above can be realized in a digital electronic circuit system, integrated circuit system, field-programmable gate array (FPGA), application-specific integrated circuit (ASIC), application-specific standard product (ASSP), system-on-chip (SOC) system, complex programmable logic device (CPLD), computer hardware, firmware, software, and/or a combination thereof. These implementations can be implemented in one or more computer programs, which can be executed and/or explained in a programmable system including at least one programmable processor. The programable processor can include a special-purpose or general-purpose programmable processor, which can receive data and instructions from a storage system, at least one input apparatus, and at least one output apparatus, and transmit the data and instructions to the storage system, the at least one input apparatus, and the at least one output apparatus.

Program codes for implementing the method of the present disclosure can be written in any combination of one or more programming languages. The program codes can be provided to a processor or controller of a general-purpose computer, special-purpose computer, or other programmable data processing apparatus. Thus, when the program codes are executed by the processor or controller, the functions/operations specified in the flowcharts and/or block diagrams can be implemented. The program codes can be executed entirely on a machine, partly on the machine, partly on the machine as an individual software package, and partly on a remote machine, or entirely on a remote machine or server.

In the context of the present disclosure, a machine-readable medium can be a tangible medium that can include or store a program for use by or in connection with an instruction execution system, apparatus, or device. The machine-readable medium can be a machine-readable signal medium or a machine-readable storage medium. The machine-readable medium can include, but is not limited to, electronic, magnetic, optical, electromagnetic, infrared, or semiconductor systems, apparatuses, or devices, or any suitable combination thereof. Moreover, the machine-readable storage medium can further include electrical connections based on one or more wires, portable computer disks, hard disks, random access memory (RAM), read-only memory (ROM), erasable programmable read-only memory (EPROM or flash memory), optical fibers, portable compact disc read-only memory (CD-ROM), optical storage devices, magnetic storage devices, or any suitable combination thereof.

To provide interaction with users, the systems and technologies described here can be implemented on a computer equipped with a display apparatus (e.g., a CRT (cathode-ray tube) or LCD (liquid crystal display) monitor) for displaying information to the user, and a keyboard and a pointing device (e.g., a mouse or trackball) through which the user can provide input to the computer. Other types of devices can also be configured to interact with users. For example, feedback provided to the user can be any form of sensory feedback (e.g., visual, auditory, or tactile feedback). The input from the user can be received in any form, including acoustic, speech, or tactile input.

The systems and technologies described here can be implemented in a computing system that includes a back-end member (e.g., a data server), a computing system that includes a middleware member (e.g., an application server), a computing system that includes a front-end member (e.g., a user computer with a graphical user interface or web browser through which the user can interact with the implementation of the systems and technologies described here), or a computing system that includes any combination of such back-end member, middleware member, or front-end member. The members of the system can be interconnected by any form or medium of digital data communication (e.g., a communication network). The communication networks can include local area networks (LANs), wide area networks (WANs), and the Internet.

A computer system can include a client and a server. The client and the server are generally away from each other and typically interact through a communication network. The client-server relationship can be generated through the computer program running on the respective computers and establishing a client-server relationship with each other. The server can be a cloud server, a server of a distributed system, or a server in connection with blockchain technology.

The various forms of processes shown above can be reordered, and steps can be added to or removed from the processes. For example, the steps of the present disclosure can be executed in parallel, sequentially, or in a different order, as long as the desired results of the technical solutions of the present disclosure can be achieved, which is not limited to the present disclosure.

The above are merely some embodiments of the present disclosure. However, the scope of the present disclosure is not limited to this. Those skilled in the art can easily think of changes or substitutions within the technical scope of the present disclosure. These changes and substitutions should be within the scope of the present disclosure. Therefore, the scope of the present disclosure shall be subject to the scope of the appended claims.

What is claimed is:

1. A display apparatus comprising:
a display screen including a display surface and a non-display surface facing away from the display surface; and
a temperature adjustment apparatus arranged on a side of the non-display surface of the display screen and configured to adjust a temperature difference among different areas of the display screen.

2. The display apparatus according to claim 1, wherein the temperature adjustment apparatus includes a heat transfer layer attached to the non-display surface of the display screen and including one or more of a solid heat transfer structure and a liquid heat transfer structure.

3. The display apparatus according to claim 1, wherein the temperature adjustment apparatus includes an air guide structure configured to guide a heat dissipation airflow toward the display screen.

4. The display apparatus according to claim 2, wherein the display screen bends and deforms when an external force applied to the display screen reaches a preset external force threshold, and the heat transfer layer bends and deforms with the display screen.

5. The display apparatus according to claim 1, wherein:
the liquid heat transfer structure of the temperature adjustment apparatus includes a liquid channel arranged inside the liquid heat transfer structure; and
the liquid channel includes a plurality of curved channel segments and a plurality of parallel straight channel segments, a curved channel segment is arranged on one side of two neighboring straight channel segments and connects the two neighboring straight channel segments, and liquid in the liquid channel transfers heat from the display screen.

6. The display apparatus according to claim 1, further comprising a fluid driver configured to be connected to a liquid channel of the temperature adjustment apparatus to form a circulating heat transfer loop.

7. The display apparatus according to claim 6, further comprising a temperature monitor configured to monitor a temperature of the display apparatus;
wherein the temperature monitor is connected to the fluid driver and is configured to, in response to the temperature difference among the areas of the display screen being greater than a temperature threshold, control the fluid driver to drive liquid in the circulating heat transfer loop to flow to adjust the temperature difference among different areas of the display screen.

8. The display apparatus according to claim 6, wherein the fluid driver is configured to adjust a vibration frequency of a vibration membrane according to the temperature difference among the areas of the display screen to adjust a flow speed of the liquid in the liquid channel.

9. A heat transfer control method, applied to a display apparatus, comprising:
in response to a temperature difference among different areas of a display screen, controlling a temperature adjustment apparatus to adjust the temperature difference of different areas of the display screen.

10. An electronic device comprising:
a display apparatus including:
a display screen including a display surface and a non-display surface facing away from the display surface; and
a temperature adjustment apparatus arranged on a side of the non-display surface of the display screen and configured to adjust a temperature difference among different areas of the display screen; and
a first space neighboring to a heat generation element of the electronic device;
wherein:
the display apparatus is configured to switch between a first status and a second status;
in the first status, the display apparatus is at least partially accommodated in the first space; and
in the second status, the display apparatus extends out of the first space.

11. The electronic device according to claim 10, wherein the temperature adjustment apparatus includes a heat transfer layer attached to the non-display surface of the display screen and including one or more of a solid heat transfer structure and a liquid heat transfer structure.

12. The electronic device according to claim 10, wherein the temperature adjustment apparatus includes an air guide structure configured to guide a heat dissipation airflow toward the display screen.

13. The electronic device according to claim 11, wherein the display screen bends and deforms when an external force applied to the display screen reaches a preset external force threshold, and the heat transfer layer bends and deforms with the display screen.

14. The electronic device according to claim 10, wherein:
the liquid heat transfer structure of the temperature adjustment apparatus includes a liquid channel arranged inside the liquid heat transfer structure; and
the liquid channel includes a plurality of curved channel segments and a plurality of parallel straight channel segments, a curved channel segment is arranged on one side of two neighboring straight channel segments and connects the two neighboring straight channel segments, and liquid in the liquid channel transfers heat of the display screen.

15. The electronic device according to claim 10, wherein the display apparatus further includes a fluid driver configured to be connected to a liquid channel of the temperature adjustment apparatus to form a circulating heat transfer loop.

16. The electronic device according to claim 15, wherein the display apparatus further includes a temperature monitor configured to monitor a temperature of the display apparatus;
wherein the temperature monitor is connected to the fluid driver and is configured to, in response to the temperature difference among the areas of the display screen being greater than a temperature threshold, control the fluid driver to drive liquid in the circulating heat transfer loop to flow to adjust the temperature difference among different areas of the display screen.

17. The electronic device according to claim 15, wherein the fluid driver is configured to adjust a vibration frequency of a vibration membrane according to the temperature difference among the areas of the display screen to adjust a flow speed of the liquid in the liquid channel.
